(19) United States
(12) Patent Application Publication
(10) Pub. No.: US 2025/0015156 A1
(43) Pub. Date: Jan. 9, 2025

(54) SEMICONDUCTOR DEVICE AND PREPARATION METHOD THEREOF

(71) Applicant: YANGTZE MEMORY TECHNOLOGIES CO., LTD., Wuhan (CN)

(72) Inventors: Zhong Zhang, Wuhan (CN); Qingfu Zhang, Wuhan (CN); Di Wang, Wuhan (CN); Wenxi Zhou, Wuhan (CN)

(21) Appl. No.: 18/396,543

(22) Filed: Dec. 26, 2023

(30) Foreign Application Priority Data
Jul. 6, 2023 (CN) 202310828116.3

(51) Int. Cl. H01L 29/423; H01L 21/28; H01L 29/78; H10B 41/27; H10B 43/27

(52) U.S. Cl. CPC H01L 29/42356; H01L 29/4011; H01L 29/7827; H10B 41/27; H10B 43/27

(57) ABSTRACT

According to one aspect of the present disclosure, a semiconductor device is provided. The semiconductor device may include a stacked layer and a top select gate layer located on the stacked layer. The semiconductor device may include a gate-line structure extending through the top select gate layer and the stacked layer. A portion of the gate-line structure that extends through the top select gate layer may be a first isolation structure, and the first isolation structure may include a contact layer in contact with the top select gate layer. The semiconductor device may include a channel structure extending through the stacked layer and a first dielectric layer located on the top select gate layer, where the first dielectric layer and the contact layer comprise different insulating materials. The semiconductor device may include a channel local contact extending through the first dielectric layer and corresponding to the channel structure.

### CROSS-REFERENCE TO RELATED APPLICATIONS

This application claims the benefit of priority to Chinese Application No. 202310828116.3, filed on Jul. 6, 2023, which is incorporated herein by reference in its entirety.

### TECHNICAL FIELD

The present disclosure relates to the field of semiconductor technology, in particular, to a semiconductor device and a preparation method of the semiconductor device.

### BACKGROUND

Etching is one operation in semiconductor manufacturing process. To ensure the etching effect, it is necessary to have a sufficient margin for the etching window when performing the etching operation on the etching stop layer, resulting in a risk of damage to other isolation structures in adjacent areas with the same material as the etching stop layer, which in turn affects the electrical performance of the semiconductor device.

It should be noted that the information disclosed in the Background section above is only used to enhance the understanding of the background of the present disclosure, and therefore may include information that does not constitute the related art known to those skilled in the art.

### SUMMARY

According to one aspect of the present disclosure, a semiconductor device is provided. The semiconductor device may include a stacked layer. The semiconductor device may include a top select gate layer located on the stacked layer. The semiconductor device may include a gate-line structure extending through the top select gate layer and the stacked layer. A portion of the gate-line structure that extends through the top select gate layer may be a first isolation structure, and the first isolation structure may include a contact layer in contact with the top select gate layer. The semiconductor device may include a channel structure extending through the stacked layer. The semiconductor device may include a first dielectric layer located on the top select gate layer, where the first dielectric layer and the contact layer include different insulating materials. The semiconductor device may include a channel local contact extending through the first dielectric layer and provided corresponding to the channel structure.

In some implementations, the semiconductor device may include a connecting structure extending through the top select gate layer. In some implementations, one end of the connecting structure may be in contact with the channel structure and the other end of the connecting structure is in contact with the channel local contact.

In some implementations, the semiconductor device may include a second dielectric layer located between the top select gate layer and the first dielectric layer. In some implementations, the connecting structure may extend through the second dielectric layer to be in contact with the channel local contact.

In some implementations, a portion of the gate-line structure that extends through the stacked layer may be a second isolation structure, and a width of the first isolation structure may be greater than a width of the second isolation structure in a direction parallel to the first dielectric layer.

In some implementations, the semiconductor device may include a core array and a staircase. In some implementations, the top select gate layer may be provided in the core array. In some implementations, the semiconductor device may further include a first contact structure provided in the core array, extending through the first dielectric layer and the second dielectric layer and extending to the top select gate layer. In some implementations, the semiconductor device may further include a second contact structure provided in the staircase, extending through the first dielectric layer and extending to a step of the staircase.

In some implementations, the first contact structure may be a first substructure extending through the first dielectric layer and a second substructure extending through the dielectric layer, and in a direction parallel to the first dielectric layer, at a position where the first substructure and the second substructure are connected with each other, a width of the first substructure is greater than a width of the second substructure. In some implementations, the second contact structure may include a third substructure extending through the first dielectric layer and a fourth substructure extending to the step of the staircase, and in the direction parallel to the first dielectric layer, at a position where the third substructure and the fourth substructure are connected with each other, a width of the third substructure is greater than a width of the fourth substructure.

In some implementations, in a direction parallel to the first dielectric layer, a portion of the channel local contact extending through the first dielectric layer may have a first width, a portion of the first contact structure extending through the first dielectric layer may have a second width, and a portion of the second contact structure extending through the first dielectric layer may have a third width. In some implementations, the second width may be greater than the first width, and the first width is greater than the third width.

In some implementations, the semiconductor device may include a gap contact structure extending through the first dielectric layer and communicating with the gate-line structure.

In some implementations, the semiconductor device may include a semiconductor layer provided on a side of the stacked layer away from the top select gate layer.

In some implementations, the semiconductor device may include a cap layer provided on the first dielectric layer. In some implementations, the channel local contact may extend through the cap layer and the first dielectric layer and may be in contact with the channel structure.

In some implementations, the first dielectric layer and the cap layer may include different insulating materials. In some implementations, the first dielectric layer and the second dielectric layer comprise different insulating materials.

In some implementations, a top select gate cut located between the first dielectric layer and the stacked layer and extending through the top select gate layer. In some implementations, the top select gate cut and the first dielectric layer may include the same insulating material or different insulating materials.

In some implementations, the different insulating materials may include at least two of silicon nitride, insulation oxide, or silicon oxynitride.

According to another aspect of the present disclosure, a semiconductor device is provided. The semiconductor device may include a stacked layer. The semiconductor device may include a top select gate layer located on the stacked layer. The semiconductor device may include a gate-line structure extending through the top select gate layer and the stacked layer. The semiconductor device may include a channel structure extending through the stacked layer. The semiconductor device may include a first dielectric layer located on the top select gate layer and covering the gate-line structure. The semiconductor device may include a channel local contact extending through the first dielectric layer and provided corresponding to the channel structure.

According to a further aspect of the present disclosure, a method of preparing a semiconductor device. The method may include providing a base substrate. The base substrate may include a substrate, a stacked layer located on the substrate, a top select gate layer located on the stacked layer, a channel structure extending through the stacked layer and extending to the substrate, and a gate-line structure extending through the top select gate layer and the stacked layer and extending to the substrate. The method may include forming a first dielectric layer, where the first dielectric layer is located on the top select gate layer. The method may include forming a channel local contact, where the channel local contact extends through the first dielectric layer and is provided corresponding to the channel structure.

In some implementations, the forming the first dielectric layer may include forming a second dielectric layer on the top select gate layer. In some implementations, the forming the first dielectric layer may include planarizing the second dielectric layer. In some implementations, the forming the first dielectric layer may include forming the first dielectric layer on the second dielectric layer.

In some implementations, the method may include forming a cap layer, where the cap layer is located on the first dielectric layer.

In some implementations, the semiconductor device may include a core array and a staircase. In some implementations, the forming the channel local contact may include performing an etching operation on the cap layer and the first dielectric layer in the core array to form a channel local contact window. In some implementations, the forming the channel local contact may include filling the channel local contact window with a conductive material to form the channel local contact.

In some implementations, the performing the etching operation on the cap layer and the first dielectric layer in the core array may include performing the etching operation on the cap layer in the core array to form a channel local opening. In some implementations, the performing the etching operation on the cap layer and the first dielectric layer in the core array may include etching the first dielectric layer within the channel local opening to form the channel local contact window.

In some implementations, the performing the etching operation on the cap layer and the first dielectric layer in the core array may include forming a first contact opening in the core array synchronously with the channel local contact window, where an opening size of the first contact opening is greater than a window size of the channel local contact window. In some implementations, the performing the etching operation on the cap layer and the first dielectric layer in the core array may include forming a second contact opening in the staircase synchronously with the channel local contact window, where both the first contact opening and the second contact opening extend through the cap layer and the first dielectric layer, and extend to the second dielectric layer.

In some implementations, after performing the etching operation on the cap layer and the first dielectric layer in the core array to form the channel local contact window, the method may further include etching the cap layer and the first dielectric layer in the core array to form a first contact opening, where an opening size of the first contact opening is greater than a window size of the channel local contact window. In some implementations, after performing the etching operation on the cap layer and the first dielectric layer in the core array to form the channel local contact window, the method may further include etching the cap layer and the first dielectric layer in the staircase to form a second contact opening.

In some implementations, the method may include performing the etching operation on the second dielectric layer and the top select gate layer within the first contact opening to form a first sub hole. In some implementations, the method may include performing the etching operation on the second dielectric layer and the stacked layer within the second contact opening to form a second sub hole extending to a step of the staircase.

In some implementations, the filling the channel local contact window with the conductive material may include filling the first contact opening and the first sub hole with the conductive material to form a first contact structure. In some implementations, the filling the channel local contact window with the conductive material may include filling the second contact opening and the second sub hole with the conductive material to form a second contact structure.

In some implementations, the method may include performing the etching operation on the cap layer and the first dielectric layer in an area corresponding to the gate-line structure to form a gate lead hole. In some implementations, the method may include filling the gate lead hole with a conductive material to form a gap contact structure.

In some implementations, the method may include removing the substrate to expose a substrate end, where the substrate end is a portion of the channel structure extending to the substrate.

In some implementations, the method may include forming a semiconductor layer on a side of the stacked layer away from the first dielectric layer, where the semiconductor layer covers the substrate end.

In the semiconductor device and preparation method thereof provided in implementation of the present disclosure, after forming the gate-line structure, the first dielectric layer is formed on the top select gate layer to serve as an etching stop layer, and the channel local contact is further formed on the first dielectric layer. On the one hand, during the process of etching the first dielectric layer to form the channel local contact window of the channel local contact, the gate-line structure is in a state of being covered by the first dielectric layer. On the other hand, the first dielectric layer uses an insulating material different from the contact layer of the gate-line structure. The first dielectric layer serves as the material to be etched, and the contact layer of the gate isolation structure serves as the medium that needs to be protected. By setting the etching selection ratio of the two materials reasonably, it is beneficial to reduce the impact of the etching operation of the first dielectric layer on the contact layer of the gate-line structure, thereby improving the yield rate of the semiconductor device.

The following provides a detailed description of other features and advantages of the present disclosure, as well as the structures and operations of various implementations of the present disclosure, with reference to the accompanying drawings. It should be pointed out that the present disclosure is not limited to the specific implementations described herein. Such implementations are presented here for illustrative purposes only. Based on the teachings contained herein, additional implementations will be apparent to those skilled in the art.

### BRIEF DESCRIPTION OF THE DRAWINGS

The accompanying drawings, which are incorporated in and constitute a part of this specification, illustrate implementations consistent with the present disclosure and, together with the specification, serve to explain the principles of the present disclosure. Obviously, the accompanying drawings in the following description are only some implementations of the present disclosure. For those skilled in the art, other accompanying drawings may be obtained based on these drawings without any creative labor.

FIG. 1 shows a semiconductor device according to some implementations of the present disclosure.

FIGS. 2-18 show cross-sectional views of a semiconductor device in the manufacturing process according to some implementations of the present disclosure.

FIG. 19 shows a plan view of a cross-section of a semiconductor device according to some implementations of the present disclosure.

FIG. 20 shows a flowchart of a method for forming a semiconductor device according to some implementations of the present disclosure.

FIG. 21 shows a schematic diagram of a memory system according to some implementations of the present disclosure.

FIG. 22 shows a schematic diagram of a memory card according to an implementation of the present disclosure.

FIG. 23 shows a schematic diagram of a solid-state drive (SSD) according to an implementation of the present disclosure.

### DETAILED DESCRIPTION

Although specific configurations and arrangements are discussed, it should be understood that these are for illustrative purposes only. The person skilled in the art will recognize that other configurations and arrangements can be used without departing from the spirit and scope of the present disclosure. It will be apparent to the person skilled in the art that the present disclosure can also be applied in a variety of other applications.

It is noted that references in the specification to “one implementation”, “an implementation “some implementation”, etc., indicate that the implementations described may include a particular feature, structure, or characteristic, but not every implementation necessarily includes the particular feature, structure, or characteristic. Moreover, such phrases may not necessarily refer to the same implementation. In addition, when a particular feature, structure or characteristic is described in connection with an implementation, the implementation of such feature, structure, or characteristic in conjunction with other implementations should be within the knowledge scope of those skilled in the art whether explicitly described or not.

Usually, a term can be understood at least partially from its use in the context. For example, at least partially depending on the context, the term “one or more” used herein may be used to describe a feature, a structure, or a characteristic in the singular sense, or may be used to describe a combination of feature, structure, or characteristic in the plural sense. Similarly, at least partially depending on the context, the terms such as “one” or “said” may be understood to convey singular or plural usage.

It should be readily understood that the meaning of “on”, “above”, and “over” in the present disclosure should be interpreted in the broadest manner, so that “on” not only means “directly on” something, but also includes the meaning of “on” something with an intermediate feature or layer therebetween, and “above” or “over” not only includes the meaning of “above” or “over” something, but may also include the meaning of “above” or “over” something with no intermediate feature or layer therebetween (e.g., directly on something).

In addition, as shown in the drawings, space-related terms, such as “beneath”, “below”, “lower”, “above”, “upper” and the like, may be used herein to describe the relationship between one element or feature and another one or more elements or features for ease of description. The space-related terms are intended to encompass different orientations of the device in use or operation in addition to the orientation depicted in the drawings. The device may be otherwise oriented (rotated 90 degrees or at other orientations), and the spatially relative descriptors used herein may likewise be interpreted accordingly.

As used herein, the term “substrate” refers to a material onto which subsequent material is added or otherwise set. The substrate itself may be patterned. The material set on (for example, on the top of) the substrate may be patterned or may remain unpatterned. In addition, the substrate may include a wide range of semiconductor materials, such as silicon, germanium, gallium arsenide, indium phosphide, etc. Alternatively, the substrate may be made from a non-conductive material, such as a glass, a plastic, or a sapphire wafer.

As used herein, the term “layer” refers to a part of material including a region having a thickness. A layer may extend over the entirety of an underlying or overlying structure, or may have an extent less than the extent of an underlying or overlying structure. In addition, a layer may be a region of a homogeneous or heterogeneous continuous structure that has a thickness less than the thickness of the continuous structure. A Layer may extend horizontally, vertically, and/or along a tapered surface. A substrate may be a layer, which may include one or more layers, and/or may have one or more layers there on, there above, and/or there below. A layer may include multiple layers. For example, a stacked layer may include one or more conductors and contact layers (in which contacts, interconnection lines, and/or through holes are formed) as well as one or more dielectric layers.

As used herein, the term “nominal/nominally” refers to a desired or target value of a characteristic or parameter for a component or a process operation, set during the design phase of a product or a process, as well as a range of values above and/or below the desired value. The range of values may be caused by slight variations in the manufacturing process or tolerance. As used herein, the term “about” indicates the value of a given quantity that may vary based on a particular technology node associated with the subject semiconductor device. Based on the particular technology node, the term “about” may indicate a value of a given quantity that varies within, for example, 10-30% of the value (e.g., +10%, +20%, or +30% of the value).

As used herein, “semiconductor device” refers to a semiconductor device with vertically oriented strings of memory cell transistors (referred to as “memory strings” herein, such as NAND strings) on a laterally-oriented substrate so that the memory strings extend in the vertical direction with respect to the substrate. As used herein, the term “vertical/vertically” means nominally perpendicular to a lateral surface of a substrate.

As used herein, the term “horizontal/horizontally/lateral/laterally” means nominally parallel to the lateral surface of the substrate, and the term “vertical” or “vertically” means nominally perpendicular to the lateral surface of the substrate.

As used herein, “semiconductor device” may specifically refer to a “3D memory device”. In certain 3D memory devices such as 3D NAND memory devices, the gap structure (e.g., the gate-line structure (GLS)) is configured to provide an electrical connection from a front of the device to a source of the storage array (e.g., the array common source (ACS)).

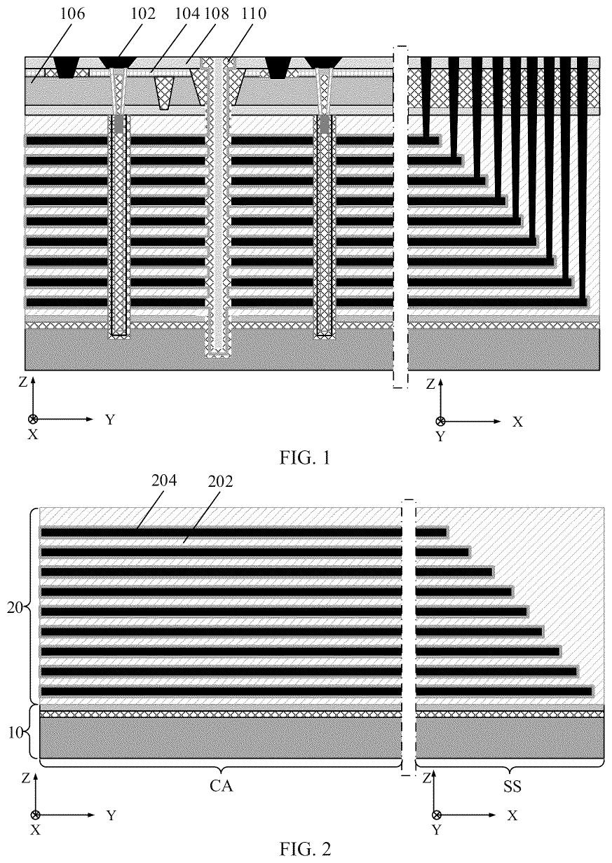

As shown in FIG. 1, in order to form a channel local contact 102 (C1CH) on the top select gate layer 106 (TSG), the process used is to perform an etching operation on the etching stop layer 108 above the top select gate layer and stop the etching operation at the dielectric layer 104, where the etching stop layer 108 may be an oxide material. The wet etching and/or dry etching (such as reactive-ion etching (RIE)) is used to extend through the etching stop layer 108 to form a channel local contact window. The channel local contact window is filled with the conductive material to form the channel local contact. Due to a small distance between the channel local contact 102 and the gate-line structure 110 (GLS), during etching, it is necessary to ensure a sufficient margin of the etching window. Moreover, the material of the contact layer of the gate-line structure 110 extending through the top select gate layer 106 and being in contact with the top select gate layer 106 is made of the same oxide material as the etching stop layer 108. Because the etching parameters of the same material are the same, there is a significant risk of etching onto the contact layer of the gate-line structure 110 during etching, causing damage to the contact layer and causing an abnormal electrical connection between the top select gate layer 106 and a conductive portion inside the gate-line structure 110, ultimately reducing the yield rate of the semiconductor device.

In addition, in order to separately form the channel local contact and other contact structures, different mask plates need to be configured for respectively etching the channel local contact window and etching the contact opening(s) of other contact structure(s) during the etching operation. This process also results in an increase in the number of mask plates and corresponding processes.

According to various implementations of the present disclosure, a semiconductor device is provided, which includes a stacked layer, a top select gate layer located on the stacked layer, and a gate-line structure that extends through the top select gate layer and the stacked layer. After forming the gate-line structure, a first dielectric layer is formed on the top select gate layer as an etching stop layer, and a channel local contact is further formed on the etching stop layer. On the one hand, during the process of etching the etching stop layer to form the channel local contact window of the channel local contact, the gate-line structure is in a state of being covered by the etching stop layer. On the other hand, the etching stop layer uses an insulating material different from the contact layer of the gate-line structure, the etching stop layer serves as the dielectric layer that needs to be etched, and the contact layer of the gate isolation structure serves as the dielectric layer that needs to be protected. By setting the etching selection ratio of the two materials reasonably, it is beneficial to reduce the impact of the etching operation of the etching stop layer on the contact layer of the gate-line structure, thereby improving the yield rate of the semiconductor device.

It should be noted that FIGS. 1 to 19 include x, y, and z axes to illustrate the spatial relationships of components in the semiconductor device. The x-direction and y-direction are two orthogonal directions in the semiconductor plane: the x-direction is a word line direction, and the y-direction is a bit line direction. The z-axis is perpendicular to the x-axis and the y-axis. As used herein, when the substrate (e.g., substrate 10) is located in the lowest plane of the semiconductor device in the z-direction (a vertical direction perpendicular to the x-y plane), whether one component of the semiconductor device is “on”, “above” or “below” another component (e.g., a layer or a device) in the z-direction may be determined with respect to the substrate 10 of the semiconductor device. Throughout the present disclosure, the same concepts used to describe spatial relationships have been applied.

In addition, as shown in FIGS. 1 to 19, the semiconductor device includes a core array (CA) and a staircase (SS).

As shown in FIG. 2, in some implementations, the semiconductor device includes a semiconductor layer 10.

In some implementations, the semiconductor layer 10 may be a substrate 10, which may include silicon (such as monocrystalline silicon, c-Si), silicon germanium (SiGe), gallium arsenide (GaAs), germanium (Ge), silicon on insulator (SOI), or any other suitable material.

The semiconductor device further includes a stacked layer 20 formed on the substrate 10. In an initial stage, the stacked layer 20 includes alternating interlayer insulation layers 202 and interlayer sacrificial layers 204. The interlayer insulation layer 202 is specifically an oxide, the interlayer sacrificial layer 204 is specifically a nitride, and the interlayer sacrificial layer 204 will be replaced with a conductor layer in subsequent processes. The interlayer insulation layer 202 and the interlayer sacrificial layer 204 alternate in a vertical direction (such as along the z-axis). In other words, except for the layer on the top or bottom of the stacked layer 20, each interlayer insulation layer 202 may be adjacent by two interlayer sacrificial layers 204 on both sides, or each interlayer sacrificial layer 204 may be adjacent by two interlayer insulation layers 202 on both sides. The interlayer insulation layers 202 may all have the same thickness or different thicknesses. Similarly, the interlayer sacrificial layers 204 may all have the same thickness or different thicknesses. For example, rather than limiting, the thickness of each interlayer insulation layer 202 may range from about 25 nm to about 40 nm, and the thickness of each interlayer sacrificial layer 204 may range from about 20 nm to about 35 nm.

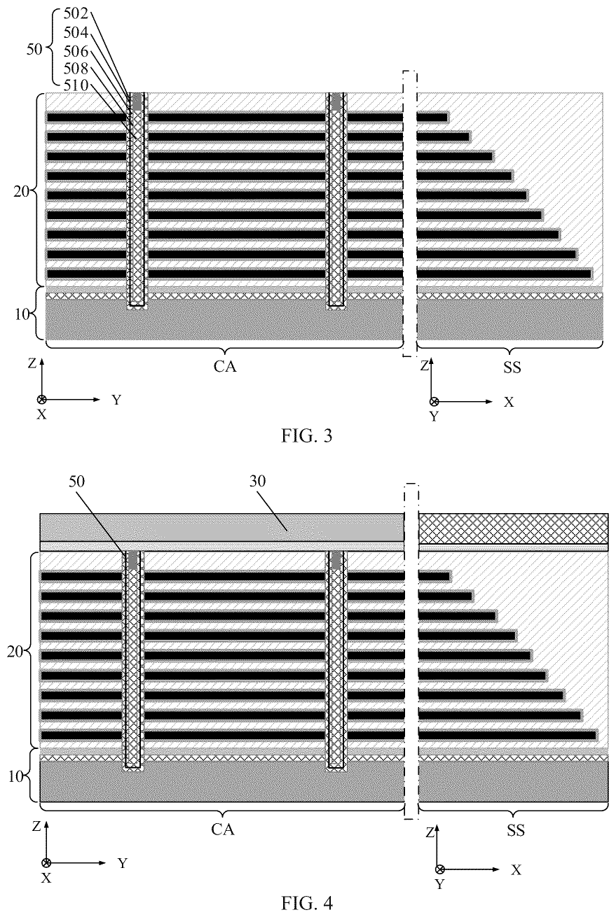

In some implementations, as shown in FIG. 3, the semiconductor device further includes a channel structure 50 that extends through the stacked layer 20. Specifically, the channel structure 50 may specifically include a channel hole (CH) and a barrier dielectric layer 502, a charge trapping layer 504, a tunneling dielectric layer 506, a channel layer 508, and a filling layer 510 which are sequentially stacked along a radial direction of the channel hole. In practical applications, the barrier dielectric layer 502, the charge trapping layer 504, the tunneling dielectric layer 506, and the channel layer 508 are formed in this order along the sidewall and bottom surface of the channel hole. The barrier dielectric layer 502 is used to block the charge flowing out of the storage layer, and the charge trapping layer 504 is used to capture and store the charge.

In some implementations, as shown in FIG. 4, after forming the channel structure 50, a top select gate layer (TSG deck) 30 is further formed.

In some implementations, in other process flows, the top select gate layer 30 may be formed first, and then the channel structure 50 that extends through the top select gate layer 30 and the stacked layer 20 may be formed.

As a way of forming the top select gate layer 30, the specific operations may include first forming a top stacked layer on the stacked layer 20, and removing the top sacrificial layer in the top stacked layer via the gate gap to form a top interlayer gap, so as to form the top select gate layer 30 within the top interlayer gap.

As shown in FIG. 8, in some implementations, the semiconductor device further includes a gate-line structure 40, which extends through the top select gate layer 30 and the stacked layer 20. A portion of the gate-line structure 40 that extends through the top select gate layer 30 is a first isolation structure 402, which includes a contact layer 4022 in contact with the top select gate layer.

In order to form a gate-line structure, a gate line gap (not shown in the drawings) that extends through the top select gate layer 30 and the stacked layer 20 is first formed, the interlayer sacrificial layer 204 is removed through the gate line gap, and a conductor layer 206 is formed at the original position of the interlayer sacrificial layer 204, as shown in FIG. 8. The conductor layer may include a metal layer (not shown in the drawings), and the metal specifically includes tungsten, etc.

Specifically, the gate-line structure 40 is configured to separate the storage block of the semiconductor device into multiple storage fingers.

In some implementations, the gate-line structure 40 further extends to the substrate.

Specifically, in order to form the gate-line structure 40, a gate line gap in the stacked layer 20 and the top select gate layer 30 is first formed, and the gate line gap vertically extends through the top select gate layer 30 along the Z-direction.

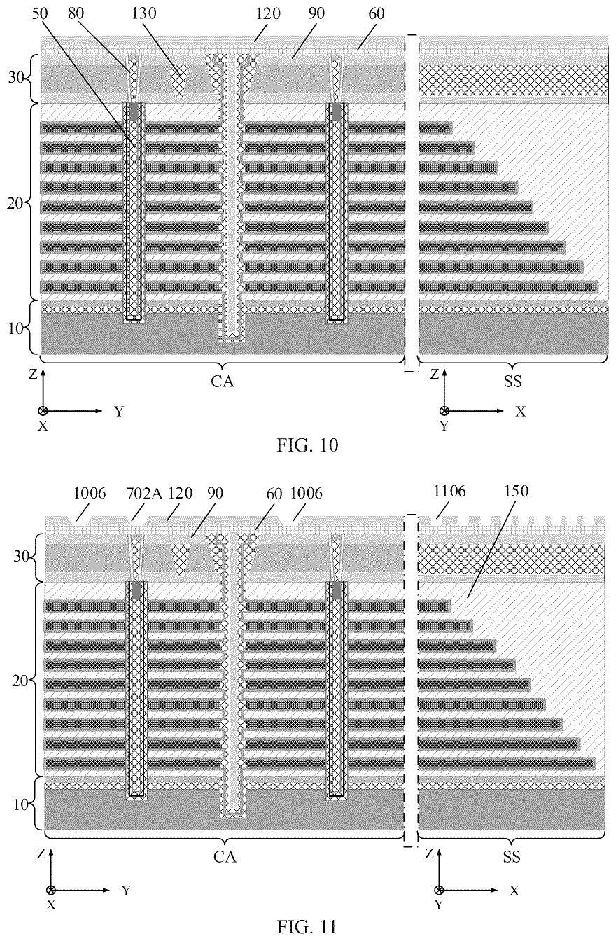

As shown in FIG. 10, in some implementations, the semiconductor device further includes: a cap layer 120 provided on the first dielectric layer 60, the first dielectric layer 60 may serve as an etching stop layer, and a channel local contact 70 extends through the cap layer 120 and the first dielectric layer 60 and is in contact with the channel structure 50. The cap layer 120 may include silicon oxide, silicon nitride, silicon oxynitride, TEOS, or a combination thereof. The cap layer 120 may be deposited through a chemical vapor deposition (CVD), a physical vapor deposition (PVD), an atomic layer deposition (ALD), sputtering, or the like.

In some implementations, the gate line gap also extends through the cap layer 120.

In some implementations, the gate line gap extends into the substrate, and the gate line gap may be formed through the photolithography process and the etching process. The etching process may include any suitable dry etching, wet etching, and/or a combination thereof, and the gate line gap may extend laterally along the WL direction.

Specifically, the gate-line structure 40 includes a gate line isolation layer 406 provided on a sidewall of the gate line gap, and the gate line isolation layer 406 may include any suitable insulator, such as silicon oxide, silicon nitride, silicon oxynitride, boron or phosphorus doped silicon oxide, carbon doped oxide (CDO or SiOC or SiOC: H), or fluorine doped oxide (SiOF), or any combination thereof. The gate line isolation layer 406 may be deposited by using, for example, ALD, CVD (such as PECVD, RTCVD, LPCVD, etc.), PVD, sputtering, evaporation, or any other suitable film deposition techniques.

In some implementations, before the gate line isolation layer 406 is deposited, a portion of the substrate 10 may be exposed inside the gate line gap. In some implementations, a portion of the gate line isolation layer 406 located at the bottom of the gate line gap may also be removed by dry etching process or wet etching process after the gate line isolation layer 406 is deposited, to expose a portion of the substrate 10 located inside the gate line gap.

The gate-line structure 40 further includes a conductive core 408 provided inside the gate line gap. The conductive core 408 fills the gate line gap with the conductive material, and the conductive core 408 may contact an exposed portion of the substrate inside the gate line gap to form an electrical connection with the substrate 10.

A portion of the gate line isolation layer 406 and a portion of the conductive core 408 that extends through the top select gate layer 30 form a first isolation structure 402, and a portion of the gate line isolation layer 406 and a portion of the conductive core 408 that extends through the stacked layer 20 form a second isolation structure 404.

In addition, a contact layer 4022 of the first isolation structure 402 in contact with the top select gate layer belongs to a part of the gate line isolation layer 406.

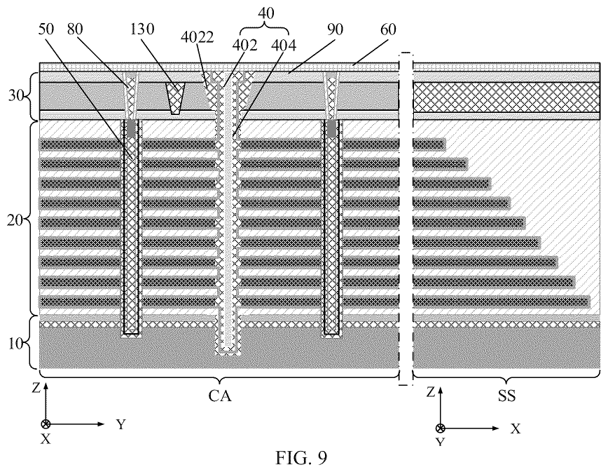

As shown in FIG. 9, in some implementations, the semiconductor device further includes a first dielectric layer 60, the first dielectric layer 60 serves as an etching stop layer, and is located on the top select gate layer 30. The first dielectric layer 60 and the contact layer 4022 include different insulating materials. For example, the contact layer 4022 includes silicon oxide, and the first dielectric layer 60 includes silicon nitride. By configuring different insulating materials for the first dielectric layer 60 and the contact layer 4022, the etching operation on the first dielectric layer 60 has a relatively small impact on the adjacent contact layer 4022, thereby reducing the probability of the gate line isolation layer 406 being damaged to cause electric leakage.

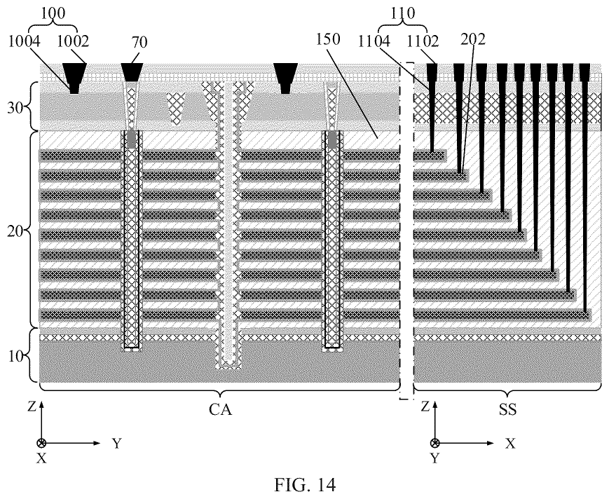

As shown in FIG. 14, in some implementations, the semiconductor device further includes a channel local contact (C1CH) 70, the channel local contact (C1CH) 70 extends through the first dielectric layer and is provided corresponding to the channel structure 50 to be electrically connected to the channel structure 50, so that each channel local contact 70 is electrically connected to a bit line contact used for bit line fanout.

As shown in FIG. 6, in some implementations, the semiconductor device further includes a second dielectric layer 90 located between the top select gate layer 30 and the first dielectric layer 60.

In some implementations, in order to form the channel local contact 70, a second dielectric layer 90 may be formed on the top select gate layer 30 by depositing a dielectric material such as silicon oxide or silicon nitride on top of the top select gate layer 30 using one or more thin film deposition processes such as CVD, PVD, ALD, or any combination thereof. The channel local contact window 702 is etched through the first dielectric layer 60 and the cap layer 120 (and any other ILD layer) on the upper side of the second dielectric layer 90 using the wet etching and/or dry etching (such as RIE), then the channel local contact window 702 is filled with the conductive material using one or more thin film deposition processes (such as ALD, CVD, PVD, any other suitable process, or any combination thereof), and thus the channel local contact 70 is formed.

In some implementations, as shown in FIG. 11, the etching operation is performed on the cap layer 120 first to form a partial channel local contact window 702A.

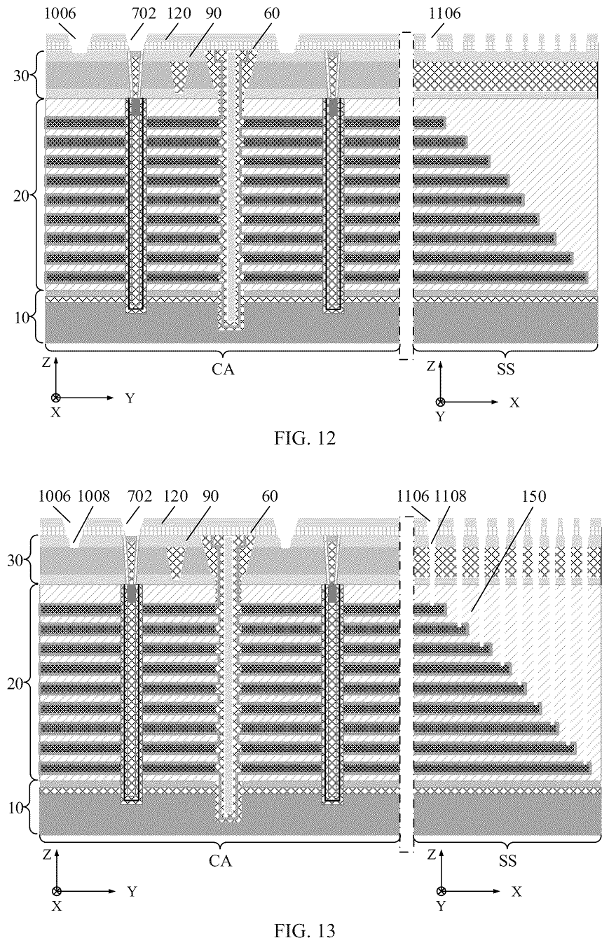

In some implementations, as shown in FIG. 12, the etching operation is further performed on the first dielectric layer 60 to form a complete channel local contact window 702.

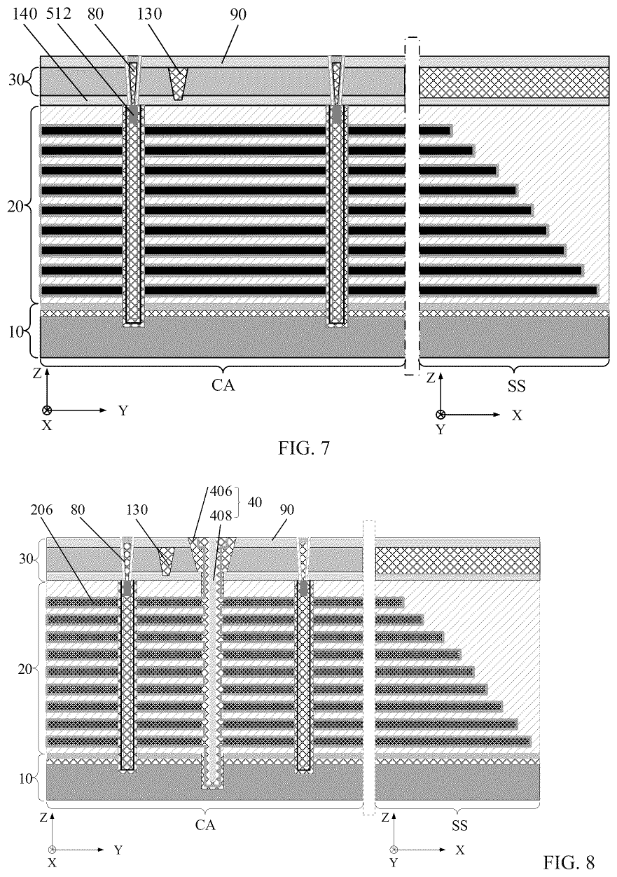

As shown in FIG. 7, in some implementations, the semiconductor device further includes a connecting structure 80 extending through the top select gate layer 30. One end of the connecting structure 80 is in contact with the channel structure 50, and the other end of the connecting structure 80 is in contact with the channel local contact 70. The connecting structure 80 extends through the second dielectric layer 90 and is in contact with the channel local contact 70 to achieve an electrical connection between the channel local contact 70 and the channel structure 50.

After forming the channel structure 50, a connecting structure 80 that extends through the second dielectric layer 90 and the top select gate layer 30 may be formed at a position corresponding to the channel structure 50 by, for example, a dry etching process or a combination of dry and wet etching processes. In addition, other manufacturing processes may also be performed, such as patterning processes including lithography, cleaning, and chemical mechanical polishing. The connecting structure 80 may have a cylindrical or columnar shape similar to the channel structure 50 in the Z-direction.

The connecting structure 80 includes a connecting structure opening, a conductive layer formed on an inner wall of the connecting structure opening, and an opening filling layer, where the conductive layer is electrically connected to the channel structure 50 and may be formed on the inner wall of the connecting structure opening through one or more thin film deposition processes, such as CVD, PVD, ALD, or any combination thereof. In some implementations, the conductive layer may include silicon, such as amorphous silicon, polysilicon, or monocrystalline silicon. The material of the conductive layer may include, but is not limited to, P-type doped polysilicon. In addition, the channel structure 50 further includes a top contact structure 512 located at the top of the structure, and the top contact structure 512 is configured to provide an electrical contact to the channel structure 50. The top contact structure 512 may be amorphous silicon or polysilicon, and may include metal, metal alloy, and/or metal silicide, such as tungsten, titanium, tantalum, tungsten nitride, titanium nitride, tantalum nitride, nickel silicide, cobalt silicide, tungsten silicide, titanium silicide, or a combination thereof. As an option, the conductive layer of the connecting structure 80 may be prepared from the same material as the top contact structure 512.

In some implementations, the semiconductor device may be a NAND memory, and the top contact structure 512 is used as a drain of the NAND memory string.

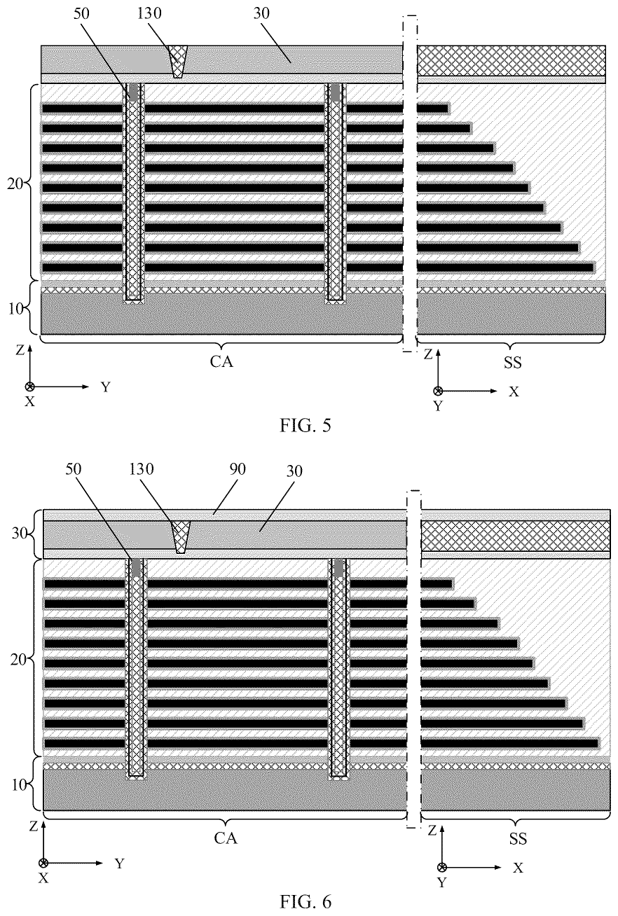

As shown in FIG. 5, in some implementations, the semiconductor device further includes a top select gate cut 130 located between the first dielectric layer 60 and the stacked layer 20 and extending through the top select gate layer 30. The top select gate cut 130 and the first dielectric layer 60 include the same insulating material or different insulating materials.

As shown in FIG. 7, the top select gate cut 130 and the connecting structure 80 are arranged in parallel. By making the size of the connecting structure 80 in the Y-direction smaller than an opening size of the top of the channel structure 50 on the side away from the substrate 10, it is more advantageous to form the top select gate cut 130 arranged in parallel with the connecting structure 80 in the Y-direction in the three-bit storage structure.

In some implementations, the semiconductor device further includes a third dielectric layer 140 located between the top select gate layer 30 and the stacked layer 20.

The top select gate cut 130 extends through the top select gate layer 30 and extends into the third dielectric layer 140, where a top select transistor controlled by the top select gate layer 30 may be implemented in the subsequent process.

In some embodiments, the top select gate cut 130 may be formed through the photolithography process and the etching process. The etching process may include any suitable dry etching, wet etching, and/or a combination thereof.

In some implementations, a portion of the gate-line structure 40 that extends through the stacked layer 20 is a second isolation structure 404. Along a direction parallel to the first dielectric layer 60, a width of the first isolation structure 402 is greater than a width of the second isolation structure 404.

In some implementations, in the Y-direction, by configuring the width of the first isolation structure 402 to be greater than the width of the second isolation structure 404, a thickness of the gate line isolation layer 406 of the first isolation structure 402 can be increased, so as to further reduce the probability of electrical damage to the gate-line structure 40.

In some implementations, the semiconductor device includes a core array (CA) and a staircase (SS), and the top select gate layer 30 is provided in the core array. The semiconductor device further includes a first contact structure 100 provided in the core array and extends through the first dielectric layer 60 and the second dielectric layer 90 to extend to the top select gate layer 30.

In some implementations, the semiconductor device further includes a second contact structure 110 provided in the staircase and extends through the first dielectric layer 60 to extend to the step of the staircase.

The core array (CA) includes an area where the channel structure 50 and the gate-line structure 40 are located. As shown in FIG. 19, the core array (CA) further includes the top select gate cut 130, and the channel local contacts 70 divided by the top select gate cut 130.

The staircase (SS) includes a step region in the stacked layer 20. Based on the arrangement of the step region, the gate electrode layer on each step in the stacked layer 20 is led out and connected to the bit line by means of a second contact structure 110.

In addition, through the gate-line structure 40, the gate-line structure 50 vertically extends through the stacked layer 20 and is configured to separate a storage block into multiple storage fingers.

In some implementations, due to the formation of the channel local contact window 702 and the formation of other first contact opening 1006 and second contact opening 1106 are both achieved through the etching operation on the first dielectric layer, only one mask plate can be used to form the channel local contact window and other contact openings. This method can reduce the use of mask plate and reduce process operations.

In other implementations, different mask plates may also be used to etch the channel local contact window 702, the first contact opening 1006, and the second contact opening 1106, respectively.

In some implementations, the first contact structure 100 includes a first substructure 1002 extending through the first dielectric layer 60 and a second substructure 1004 extending through the dielectric layer 90.

In some implementations, in a semiconductor structure provided with a cap layer 120, the first contact structure 100 includes a first substructure 1002 extending through the cap layer 120 and the first dielectric layer 60, and a second substructure 1004 extending through the dielectric layer 90.

As shown in FIG. 13, the first substructure 1002 corresponds to the first contact opening 1006, and the second substructure 1004 corresponds to the first sub hole 1008.

In some implementations, along a direction parallel to the first dielectric layer 60, at a position where the first substructure 1002 and the second substructure 1004 are connected with each other, a width of the first substructure 1002 is greater than a width of the second substructure 1004. That is, a stepped structure is formed at the position where the first substructure 1002 and the second substructure 1004 are connected with each other.

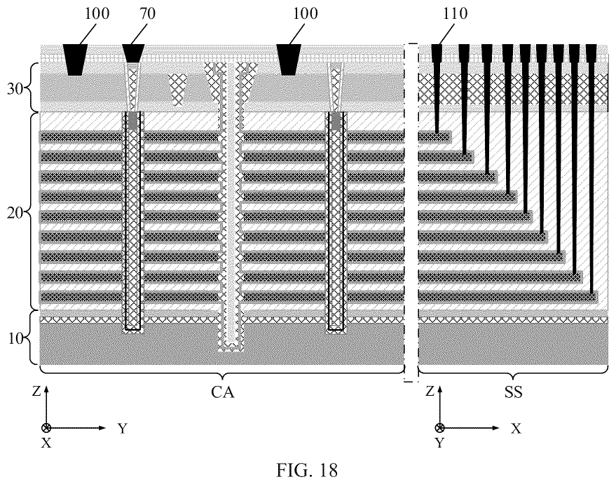

In other implementations, the first substructure 1002 and the second substructure 1004 are an integrated structure, that is, there is no stepped structure at the position where the first substructure 1002 and the second substructure 1004 are connected with each other, but the width of the first contact opening 100 in the Y-direction gradually decreases in the direction close to the substrate 10, to form a frustum shaped structure, as the first contact structure 100 shown in FIG. 18.

The first contact structure 100 is specifically the top select gate layer contact structure (TSGCT), used to achieve an electrical connection with the top select gate layer 30.

In some implementations, at the position where the first substructure 1002 and the second substructure 1004 are connected with each other, the width of the first substructure 1002 is configured to be greater than the width of the second substructure 1004. That is, along a direction close to the substrate 10, the width of the structure gradually decreases to ensure an electrical connection and facilitate the arrangement of the adjacent connecting structure 80.

In some implementations, the second contact structure 110 includes a third substructure 1102 extending through the first dielectric layer 60 and a fourth substructure 1104 extending to a step of the staircase.

As shown in FIG. 13, the third substructure 1102 corresponds to the second contact opening 1106, and the fourth substructure 1104 corresponds to the second sub hole 1108.

As shown in FIG. 14, the second contact structure 110 is specifically a word line contact structure, and the stacked layer 20 may have multiple second contact structures 110. The second contact structure 110 is formed in the third dielectric layer 150 and placed on the corresponding word line layer 202 in the staircase (SS) to connect to the word line layer 202. The second contact structure 110 may include W, Co, or other suitable conductive materials. In some implementations, a transition layer may further be formed between the second contact structure 110 and the third dielectric layer 150.

In some implementations, along the direction parallel to the first dielectric layer 60, at the position where the third substructure 1102 and the fourth substructure 1104 are connected with each other, a width of the third substructure 1102 is configured to be greater than a width of the fourth substructure 1104. That is, a step structure is formed at the position where the third substructure 1102 and the fourth substructure 1104 are connected with each other, where the fourth substructure 1104 is connected to the corresponding word line layer 202 by extending to the staircase.

In some implementations, at the position where the third substructure 1102 and the fourth substructure 1104 are connected with each other, the width of the third substructure 1102 is configured to be greater than the width of the fourth substructure 1104. That is, along a direction close to the substrate 10, the width of the structure gradually decreases to ensure the reliability of the connection with the corresponding word line layer 202.

In some implementations, along a direction parallel to the first dielectric layer 60, a portion of the channel local contact 70 extending through the first dielectric layer 60 has a first width, a portion of the first contact structure 100 extending through the first dielectric layer 60 has a second width, and a portion of the second contact structure 110 extending through the first dielectric layer 60 has a third width. The second width is greater than the first width, and the first width is greater than the third width.

In some implementations, the portion of the channel local contact 70 that passes through the first dielectric layer 60 is defined.

In some implementations, the semiconductor device further includes a conductive core 408 that extends through the first dielectric layer 60 and is communicated with the gate-line structure 40.

As shown in FIG. 16, an etching operation is performed on the region corresponding to the gate-line structure 40 on the cap layer 120 and the first dielectric layer 60 to form a gate lead hole 407.

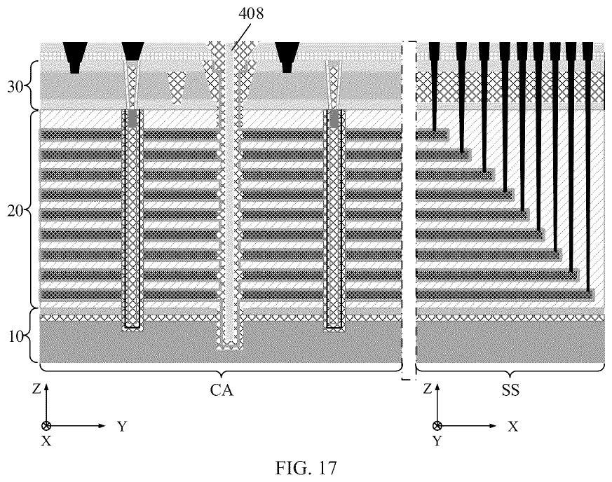

As shown in FIG. 17, the gate lead hole 407 is filled with the conductive material to form conductive core 408, so that the gate-line structure 40 can be electrically led out as an ACS and electrically connected with other external structure(s) of the semiconductor device.

In some implementations, the formation of the gate lead hole 407 and the channel local contact window 702, and the formation of the first contact opening 1006 and the second contact opening 1106 are both achieved through the etching operation on the first dielectric layer. Therefore, only one mask plate can be used to form the channel local contact window and other contact openings. This method can reduce the use of the mask plate and reduce process operations.

In other implementations, different mask plates may also be used to etch the gate lead hole 407, the channel local contact window 702, and the first contact opening 1006 and the second contact opening 1106, respectively.

In some implementations, the first dielectric layer 60 and the cap layer 120 include different insulating materials. The first dielectric layer 60 and the second dielectric layer 90 include different insulating materials.

If the first dielectric layer 60 is silicon carbide, the cap layer 120 and the second dielectric layer 90 may be silicon oxide, silicon oxynitride, TEOS, or a combination thereof.

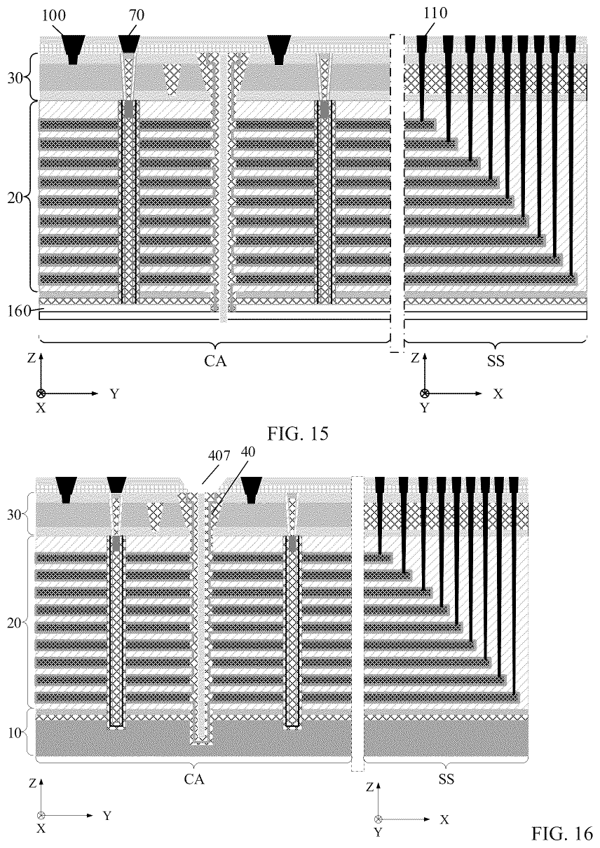

In the implementation of retaining the substrate 10, the gate-line structure 40 is used to provide an electrical connection from the front of the device to the source of the storage array (such as the array common source (ACS)). As shown in FIG. 15, in some implementations, by removing the substrate 10, a substrate end is exposed, and the substrate end is a portion of the channel structure 50 that extends to the substrate.

Specifically, CMP, grinding, dry etching, and/or wet etching may be used to remove the substrate 10. A new semiconductor layer 160 is formed on the stacked layer 20 away from the top select gate layer 30.

In the implementation of removing the substrate 10, the new semiconductor layer 160 is formed. The new semiconductor layer 160 may serve as a source layer. The gate-line isolation structure 40 may extend to the source layer, and the gate-line structure 40 may also include a conductive portion (not shown in the drawings). The conductive portion may include a conductive material. The conductive material may be a combination of one or more of tungsten, cobalt, copper, aluminum, doped silicon, and silicide, and the conductive portion may extend to the source layer to couple with the source layer.

The semiconductor layer 160 serving as the source layer may be monocrystalline silicon, single crystal germanium, III-V group compound semiconductor material, II-VI group compound semiconductor material, and other suitable semiconductor materials. In addition, it may be formed through a thin film deposition process, which may be a combination of one or more of chemical vapor deposition (CVD), physical vapor deposition (PVD), atomic layer deposition (ALD) and electroplating process.

In addition, after removing the substrate 10, the channel structure 50 may be exposed, so the formed source layer can be in contact with the exposed channel structure to achieve coupling between the source layer and the channel layer 508 in the channel structure 50.

A doped-semiconductor layer is formed on a side of the stacked layer 20 close to the substrate end, connecting the substrate ends of individual channel structures 50.

In one implementation, the material of the doped-semiconductor layer includes N-type doped polysilicon.

In one implementation, a laser-annealing process is implemented on the doped-semiconductor layer.

In one implementation, a peripheral-circuit chip is connected on a side of the stacked layer 20 away from the substrate 10.

In some implementations, the gate-line structure 40 extends into the new semiconductor layer 160.

In some implementations, different insulating materials include at least two of silicon nitride, insulation oxide, and silicon oxynitride.

The semiconductor device according to an embodiment of the present disclosure includes: a stacked layer 20; a top select gate layer 30 located on the stacked layer 20; a gate-line structure 40 extending through the top select gate layer 30 and the stacked layer 20, a portion of the gate-line structure 40 that extends through the top select gate layer 30 being the first isolation structure 402, and the first isolation structure 402 including a contact layer 4022 in contact with the top select gate layer; a channel structure 50 extending through the stacked layer 20; a first dielectric layer 60 located on the top select gate layer 30, the first dielectric layer 60 and the contact layer 4022 including different insulating materials; and a channel local contact 70 extending through the first dielectric layer and provided corresponding to the channel structure 50.

As shown in FIG. 9, a semiconductor device according to another implementation of the present disclosure includes: a stacked layer 20; a top select gate layer 30 located on the stacked layer 20; a gate-line structure 40 extending through the top select gate layer 30 and the stacked layer 20; a channel structure 50 penetrating the stacked layer 20; a first dielectric layer 60 located on the top select gate layer 30 and covering the gate-line structure; and a channel local contact 70 extending through the first dielectric layer and provided corresponding to the channel structure 50.

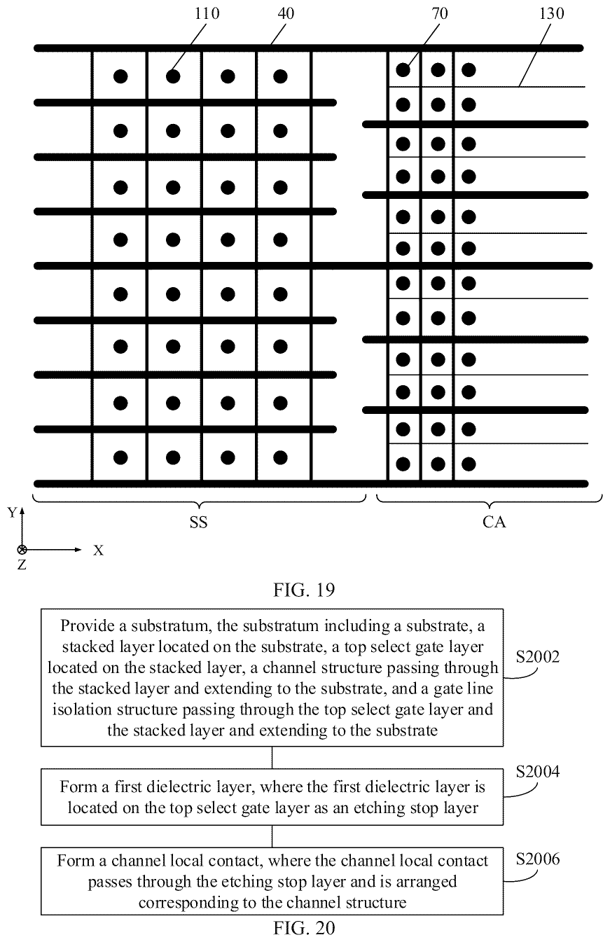

FIG. 20 is a flowchart for manufacturing the semiconductor device according to some implementations of the present disclosure, including the following operations.

At operation S2002, a base substrate is provided, the base substrate including a substrate, a stacked layer located on the substrate, a top select gate layer located on the stacked layer, a channel structure extending through the stacked layer and extending to the substrate, and a gate-line structure extending through the top select gate layer and the stacked layer and extending to the substrate.

As shown in FIG. 2, a stacked layer 20 is formed on the substrate 10.

As shown in FIG. 3, a channel structure 50 extending through the stacked layer 20 to the substrate is formed.

As shown in FIG. 4, a top select gate layer 30 is formed on the stacked layer 20.

As shown in FIG. 5, a top select gate cut 130 extending through the top select gate layer 30 is formed.

As shown in FIG. 6, a second dielectric layer 90 is formed on the top select gate layer 30.

As shown in FIG. 7, a connecting structure 80 which extends through the top select gate layer 30 and the second dielectric layer 90 and is connected to the channel structure 50 is formed.

As shown in FIG. 8, a gate-line structure 40 which extends through the top select gate layer 30 and stacked layer 20 and extends to the substrate 10 is formed.

At operation S2004, a first dielectric layer is formed, where the first dielectric layer is located on the top select gate layer as an etching stop layer.

As shown in FIG. 9, an etching stop layer 60 is formed on the second dielectric layer 90 to cover the gate-line structure 40.

As shown in FIG. 10, a cap layer 120 is formed on the first dielectric layer 60.

At operation S2006, a channel local contact is formed, where the channel local contact extends through the etching stop layer and is arranged corresponding to the channel structure.

In some implementations, the provided base substrate of the semiconductor device includes a stacked layer, a top select gate layer located on the stacked layer, and a gate-line structure that extends through the top select gate layer and the stacked layer. After forming the gate-line structure, a first dielectric layer is formed on the top select gate layer as an etching stop layer, and a channel local contact is further formed on the etching stop layer. On the one hand, during the process of etching the etching stop layer to form the channel local contact window of the channel local contact, the gate-line structure is in a state of being covered by the etching stop layer. On the other hand, the etching stop layer uses an insulating material different from the contact layer of the gate-line structure. The etching stop layer serves as the dielectric layer that needs to be etched, and the contact layer of the gate isolation structure serves as the dielectric layer that needs to be protected. By setting the etching selection ratio of the two materials reasonably, it is beneficial to reduce the impact of the etching operation of the etching stop layer on the contact layer of the gate-line structure, thereby improving the yield rate of the semiconductor device.

In some implementations, forming the first dielectric layer includes: forming a dielectric layer on the top select gate layer; planarizing the dielectric layer; and forming the first dielectric layer on the dielectric layer.

In some implementations, the method further includes forming a cap layer, which is located on the first dielectric layer.

In some implementations, the semiconductor device includes a core array (CA) and a staircase (SS), and forming the channel local contact includes: performing an etching operation on the cap layer and the first dielectric layer in the core array to form a channel local contact window; and filling the channel local contact window with a conductive material to form the channel local contact.

In some implementations, the performing the etching operation on the cap layer and the first dielectric layer in the core array, includes: performing the etching operation on the cap layer in the core array to form a channel local opening; and etching the first dielectric layer within the channel local opening to form the channel local contact window.

As shown in FIG. 11, a first mask plate is used to etch the cap layer 120, to form a channel local opening 702A.

As shown in FIG. 12, a first mask plate is used to etch the first dielectric layer 60, to form a channel local contact window 702.

In some implementations, performing the etching operation on the cap layer and the first dielectric layer in the core array, further includes the following operations.

As shown in FIGS. 11 and 12, a first mask plate is used to perform the etching operation on the cap layer 120 and the first dielectric layer 60 in the core array, respectively, to form a first contact opening 1006 synchronously with the channel local contact window 702. An opening size of the first contact opening is greater than a window size of the channel local contact window.

As shown in FIGS. 11 and 12, the first mask plate is used to perform the etching operation on the cap layer 120 and the first dielectric layer 60 in the staircase, respectively, to form a second contact opening 1106 synchronously with the channel local contact window. The first contact opening and the second contact opening both extend through the cap layer and the first dielectric layer, and extend to the second dielectric layer 90.

In some implementations, the first mask plate is used to synchronously form the channel local contact window 702, the first contact opening 1006, and the second contact opening 1106.

In some implementations, after performing the etching operation on the cap layer and the first dielectric layer in the core array to form the channel local contact window, the method further includes: etching the cap layer and the first dielectric layer in the core array to form a first contact opening, an opening size of the first contact opening being greater than a window size of the channel local contact window; and etching the cap layer and the first dielectric layer in the staircase to form a second contact opening.

In some implementations, the first mask plate is used to form the channel local contact window 702, and the second mask plate is used to form the first contact opening 1006 and the second contact opening 1106.

In some implementations, the method further includes performing the etching operation on the dielectric layer and the top select gate layer within the first contact opening to form a first sub hole; and performing the etching operation on the dielectric layer and the stacked layer within the second contact opening to form a second sub hole extending to the step of the staircase.

As shown in FIG. 13, a first sub hole 1008 is formed within the first contact opening 1006, and a second sub hole 1108 is formed within the second contact opening 1106.

In some implementations, filling the channel local contact window with the conductive material further includes filling the first contact opening and the first sub hole with the conductive material to form a first contact structure; and filling the second contact opening and the second sub hole with the conductive material to form the second contact structure.

As shown in FIG. 14, the first contact opening is filled with the conductive material to form a first opening structure 1002, the first sub hole is filled with the conductive material to form a second substructure 1004, and the first opening structure 1002 and the second substructure 1004 form a first contact structure 100.

The second contact opening is filled with the conductive material to form a third substructure 1102, the second sub hole is filled with the conductive material to form a fourth substructure 1104, and the second opening structure 1102 and the fourth substructure 1104 form a second contact structure 110.

In addition, as shown in FIG. 18, the first contact opening and the second contact opening 1106 directly extend through the dielectric layer to reach the top select gate layer, corresponding to the first contact structure 100 and the second contact structure 110 formed.

In some implementations, the method further includes removing the substrate to expose a substrate end, where the substrate end is a portion of the channel structure extending to the substrate.

In some implementations, the method includes forming a semiconductor layer on a side of the stacked layer away from the first dielectric layer, where the semiconductor layer covers the substrate end.

Furthermore, as shown in FIG. 15, the substrate is removed to expose the substrate end, and a semiconductor layer 160 connected to the substrate end is formed.

In some implementations, the method further includes performing the etching operation on the cap layer and the first dielectric layer in an area corresponding to the gate-line structure to form a gate lead hole; and filling the gate lead hole with the conductive material to form a GLS contact core.

As shown in FIG. 16, a gate lead hole 407 is formed in the area corresponding to the gate-line structure 40.

As shown in FIG. 17, the gate lead hole 407 is filled with the conductive material to form a GLS contact core 408.

In addition, an implementation of the present disclosure further provides a memory system. The memory system includes at least one semiconductor device as described in any of the above embodiments, and a controller electrically connected to the memory. The controller is further connected to an external host, and the external host can transmit user instructions and store data to the controller. The user instructions may include write instructions, erase instructions, read instructions, and the like. The controller may determine which storage location in the semiconductor device to write, erase, and read based on these contents.

For example, FIG. 21 is a block diagram of a memory system provided in an implementation of the present disclosure. The memory system 2100 may be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having a memory therein. As shown in FIG. 21, the memory system 2100 may include a host 2104 and a storage subsystem device 2102, the storage subsystem device 2102 includes one or more memories 2102A and a controller 2102B, the memory 2102A includes a storage unit array and multiple page buffers. The host 2104 may be a processor of an electronic device (such as a central processing unit (CPU)) or a system-on-chip (SoC), such as an application processor (AP). The host 2104 may be configured to send data to or receive data from the memory 2102A.

The semiconductor device of the present disclosure is a memory 2102A, or a part of the memory 2102A. According to some implementations, the controller 2102B is coupled to the memory 2102A and the host 2104, and is configured to control the memory. The controller 2102B can manage the data stored in the memory and communicate with the host 2104. In some implementations, the controller 2102B is designed for operating in a low duty-cycle environment like a secure digital (SD) card, a compact flash (CF) card, a universal serial bus (USB) flash drive, or other media for use in electronic devices, such as a personal computer, a digital camera, a mobile phone, etc. In some implementations, the controller 2102B is designed for operating in a high duty-cycle environment SSD or an embedded multi-media-card (eMMC), and the SSD or eMMC is used as a data storage for mobile devices, such as a smartphone, a tablet computer, a laptop computer, etc., and an enterprise storage device. The controller 2102B can be configured to control operations of the memory 2102A, such as read, erase, and program operations. The controller 2102B may also be configured to manage various functions regarding the data stored or to be stored in the memory 2102A, including but not limited to bad-block management, garbage collection, logical-to-physical address conversion, wear leveling, etc. In some implementations, the controller 2102B is further configured to process an error correction code (ECC) regarding the data read from or written to the memory 2102A. The controller 2102B may also perform any other suitable functions, for example, formatting the memory 2102A. The controller 2102B can communicate with an external device (e.g., the host 2104) according to a particular communication protocol. For example, the controller 2102B may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The controller 2102B and one or more memory 2102A may be integrated into various types of storage devices, for example, they are included in the same packaging (such as a universal flash storage (UFS) packaging or eMMC packaging). That is to say, the storage subsystem device 2102 may be implemented and packaged into different types of terminal electronic products.

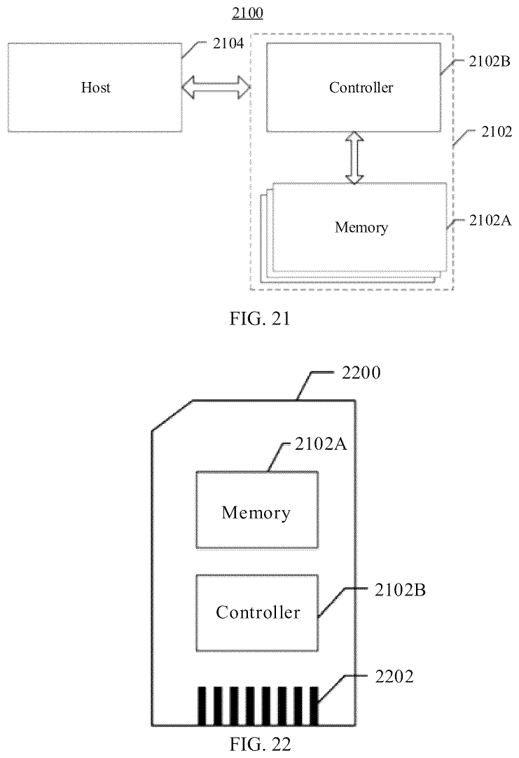

FIG. 22 is a schematic diagram of a memory card provided in the implementation of the present disclosure. In an example shown in FIG. 22, the controller 2102B and a single memory 2102A may be integrated into the memory card 2200. The memory card 2200 may include a PC card (personal computer memory card international association, PCMCIA), a CF card, a smart media (SM) card, a memory stick, a multimedia card (MMC, RS-MMC, MMC micro), an SD card (SD, miniSD, microSD, SDHC), a UFS, etc. The memory card 2200 may also include a memory card connector 2202 that couples the memory card 2200 with a host (such as the host 2104 in FIG. 21).

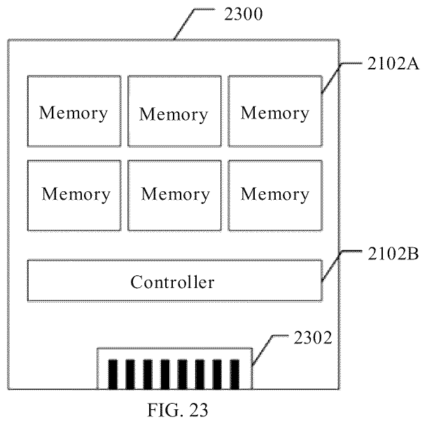

FIG. 23 is a schematic diagram of a solid-state drive (SSD) provided in the implementation of the present disclosure. As shown in FIG. 23, the controller 2102B and multiple memories 2102A may be integrated into SSD 2300. SSD 2300 may also include an SSD connector 2302 that couples SSD 2300 to a host (such as the host 2104 in FIG. 21). In some implementations, the storage capacity and/or operating speed of SSD 2300 is greater than the storage capacity and/or operating speed of the memory card 2200.

It should be noted that the structure of the memory described above is only an example structure, and for the operation method of the present application, other types of memories or memories with other structures are also applicable.

The foregoing description of the specific implementation will fully reveal the general nature of the present disclosure that others can, by applying knowledge within the technical scope of the art, readily modify and/or adjust the specific implementation for various applications, without undue experimentation and without departing from the general concept of the present disclosure. Therefore, based on the teaching and guidance presented herein, such adaptations and modifications are intended to be within the meaning and range of equivalents of the disclosed implementation. It should be understood that the phraseology or terminology herein is for the purpose of description and not of limitation, such that the terminology or phraseology in the present specification is to be interpreted by the technicians according to the above teaching and guidance.

The implementations of the present disclosure have been described above with the aid of functional building blocks, which illustrate the implementations of the specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementation of the present disclosure as contemplated by the inventor(s), and thus, are not intended to limit the present disclosure and the appended claims in any way.

The breadth and scope of the present disclosure should not be limited by any of the above-described exemplary implementation, but should be defined only in accordance with the following claims and their equivalents.

What is claimed is:

1. A semiconductor device, comprising:
a stacked layer;
a top select gate layer located on the stacked layer;
a gate-line structure extending through the top select gate layer and the stacked layer, wherein a portion of the gate-line structure that extends through the top select gate layer comprises a first isolation structure, and the first isolation structure comprises a contact layer in contact with the top select gate layer;
a channel structure extending through the stacked layer;
a first dielectric layer located on the top select gate layer, wherein the first dielectric layer and the contact layer comprise different insulating materials; and
a channel local contact extending through the first dielectric layer and corresponding to the channel structure.

2. The semiconductor device of claim 1, further comprising:
a connecting structure extending through the top select gate layer, wherein one end of the connecting structure is in contact with the channel structure and the other end of the connecting structure is in contact with the channel local contact.

3. The semiconductor device of claim 2, further comprising:
a second dielectric layer located between the top select gate layer and the first dielectric layer, wherein the connecting structure extends through the second dielectric layer to be in contact with the channel local contact.

4. The semiconductor device of claim 3, wherein:
a portion of the gate-line structure that extends through the stacked layer comprises a second isolation structure, and a width of the first isolation structure is greater than a width of the second isolation structure in a direction parallel to the first dielectric layer.

5. The semiconductor device of claim 3, wherein the semiconductor device comprises a core array and a staircase, the top select gate layer is provided in the core array, and the semiconductor device further comprises:
a first contact structure provided in the core array, extending through the first dielectric layer and the second dielectric layer and extending to the top select gate layer; and
a second contact structure provided in the staircase, extending through the first dielectric layer and extending to a step of the staircase.

6. The semiconductor device of claim 5, wherein:
the first contact structure comprises a first substructure extending through the first dielectric layer and a second substructure extending through the second dielectric layer, and in a direction parallel to the first dielectric layer, at a position where the first substructure and the second substructure are connected with each other, a width of the first substructure is greater than a width of the second substructure; and
the second contact structure comprises a third substructure extending through the first dielectric layer and a fourth substructure extending to the step of the staircase, and in the direction parallel to the first dielectric layer, at a position where the third substructure and the fourth substructure are connected with each other, a width of the third substructure is greater than a width of the fourth substructure.

7. The semiconductor device of claim 5, wherein:
in a direction parallel to the first dielectric layer, a portion of the channel local contact extending through the first dielectric layer has a first width, a portion of the first contact structure extending through the first dielectric layer has a second width, and a portion of the second contact structure extending through the first dielectric layer has a third width; and
the second width is greater than the first width, and the first width is greater than the third width.

8. The semiconductor device of claim 1, further comprising:
a conductive core extending through the first dielectric layer and communicating with the gate-line structure.

9. The semiconductor device of claim 1, further comprising:
a semiconductor layer provided on a side of the stacked layer away from the top select gate layer.

10. The semiconductor device of claim 3, further comprising:
a cap layer provided on the first dielectric layer, wherein the channel local contact extends through the cap layer and the first dielectric layer and is in contact with the channel structure.

11. The semiconductor device of claim 10, wherein:
the first dielectric layer and the cap layer comprise different insulating materials; and
the first dielectric layer and the second dielectric layer comprise different insulating materials.

12. The semiconductor device of claim 1, further comprising:
a top select gate cut located between the first dielectric layer and the stacked layer and extending through the top select gate layer, wherein the top select gate cut and the first dielectric layer comprise the same insulating material or different insulating materials.

13. The semiconductor device of claim 12, wherein the different insulating materials comprise at least two of silicon nitride, insulation oxide, or silicon oxynitride.

14. A semiconductor device, comprising:
a stacked layer;
a top select gate layer located on the stacked layer;
a gate-line structure extending through the top select gate layer and the stacked layer;
a channel structure extending through the stacked layer;
a first dielectric layer located on the top select gate layer and covering the gate-line structure; and
a channel local contact extending through the first dielectric layer and corresponding to the channel structure.

15. A method of forming a semiconductor device, comprising:
providing a base substrate, wherein the base substrate comprises a substrate, a stacked layer located on the substrate, a top select gate layer located on the stacked layer, a channel structure extending through the stacked layer and extending to the substrate, and a gate-line structure extending through the top select gate layer and the stacked layer and extending to the substrate;
forming a first dielectric layer, wherein the first dielectric layer is located on the top select gate layer; and
forming a channel local contact, wherein the channel local contact extends through the first dielectric layer and is provided corresponding to the channel structure.

16. The method of claim 15, wherein the forming the first dielectric layer, comprises:
forming a second dielectric layer on the top select gate layer;
planarizing the second dielectric layer; and
forming the first dielectric layer on the second dielectric layer, wherein the method further comprises:
forming a cap layer, wherein the cap layer is located on the first dielectric layer.

17. The method of claim 16, wherein the semiconductor device comprises a core array and a staircase, and the forming the channel local contact, comprises:
performing an etching operation on the cap layer and the first dielectric layer in the core array to form a channel local contact window; and
filling the channel local contact window with a conductive material to form the channel local contact.

18. The method of claim 17, wherein:
the performing the etching operation on the cap layer and the first dielectric layer in the core array, comprises:
performing the etching operation on the cap layer in the core array to form a channel local opening; and
etching the first dielectric layer within the channel local opening to form the channel local contact window, and
the performing the etching operation on the cap layer and the first dielectric layer in the core array, further comprises:
forming a first contact opening in the core array synchronously with the channel local contact window, wherein an opening size of the first contact opening is greater than a window size of the channel local contact window; and
forming a second contact opening in the staircase synchronously with the channel local contact window, wherein both the first contact opening and the second contact opening extend through the cap layer and the first dielectric layer, and extend to the second dielectric layer.

19. The method of claim 17, wherein after performing the etching operation on the cap layer and the first dielectric layer in the core array to form the channel local contact window, the method further comprises:
etching the cap layer and the first dielectric layer in the core array to form a first contact opening, wherein an opening size of the first contact opening is greater than a window size of the channel local contact window; and
etching the cap layer and the first dielectric layer in the staircase to form a second contact opening.

20. The method of claim 18, further comprising:
performing the etching operation on the second dielectric layer and the top select gate layer within the first contact opening to form a first sub hole; and
performing the etching operation on the second dielectric layer and the stacked layer within the second contact opening to form a second sub hole extending to a step of the staircase,
wherein the filling the channel local contact window with the conductive material, further comprises:
filling the first contact opening and the first sub hole with the conductive material to form a first contact structure; and
filling the second contact opening and the second sub hole with the conductive material to form a second contact structure.
